(19) United States
(12) Patent Application Publication
(10) Pub. No.: US 2019/0148589 A1
(43) Pub. Date: May 16, 2019

(54) ULTRAVIOLET LIGHT EMITTING DEVICE AND METHOD FOR MANUFACTURING SAME

(71) Applicants: Soko Kagaku Co., Ltd., Ishikawa (JP); AGC INC., TOKYO (JP)

(72) Inventors: Kiho YAMADA, Aichi (JP); Yosuke NAGASAWA, Nara (JP); Akira HIRANO, Aichi (JP); Masamichi IPPOMMATSU, Hyogo (JP); Ko AOSAKI, Tokyo (JP)

(73) Assignees: Soko Kagaku Co., Ltd., Ishikawa (JP); AGC INC., TOKYO (JP)

(21) Appl. No.: 16/308,687

(22) PCT Filed: Apr. 10, 2017
(86) PCT No.: PCT/JP2017/014657

§ 371 Date: Dec. 10, 2018

(30) Foreign Application Priority Data
Jul. 1, 2016 (JP) 2016-131535

(51) Int. Cl. H01L 33/22; H01L 33/56; H01L 33/32

(52) U.S. Cl. CPC H01L 33/22; H01L 2933/005; H01L 33/32; H01L 33/56

(57) ABSTRACT

Provided is an ultraviolet light emitting device that prevents peeled off of a non-bonding amorphous fluororesin and has high quality and high reliability. An ultraviolet light emitting device 1 in which a nitride semiconductor ultraviolet light emitting element 10 including a sapphire substrate 11 flip-chip mounted on a base 30 is sealed with an amorphous fluororesin 40, in which the rear surface of the sapphire substrate 11 has a polished surface having an epitaxial growth grade, or a roughened surface having an arithmetic average roughness Ra of 25 nm or more, a structural unit of a polymer or copolymer constituting the amorphous fluororesin 40 has a fluorine-containing aliphatic cyclic structure, a terminal functional group of a polymer or copolymer constituting the first resin portion that is in direct contact with the light emitting element 10 in the amorphous fluororesin 40 is a perfluoroalkyl group, and when the rear surface of the sapphire substrate 11 is the polished surface, the weight average of the first resin portion is 230000 or more, and when the rear surface of the sapphire substrate 11 is the roughened surface, the molecular weight is 160,000 or more.

### TECHNICAL FIELD

The present invention relates to an ultraviolet light emitting device in which a nitride semiconductor ultraviolet light emitting element is sealed with an amorphous fluororesin, and more particularly to a rear surface emission type ultraviolet light emitting device that extracts light having a light emission center wavelength of about 350 nm or less from the rear surface side of a substrate.

### BACKGROUND ART

Conventionally, there are a large number of nitride semiconductor light emitting elements such as light emitting diodes (LEDs) or semiconductor lasers in which a light emitting element structure including a plurality of nitride semiconductor layers is formed on a substrate such as sapphire by epitaxial growth (for example, see Non-Patent Documents 1 and 2 below). The nitride semiconductor layer is represented by the general formula Al_{1-x-y}GaₓIn_{y}N (0≤x≤1, 0≤y≤1, 0≤x+y≤1).

The light emitting element structure has a double-hetero structure in which an active layer is interposed between an n-type nitride semiconductor layer and a p-type nitride semiconductor layer. The active layer includes a nitride semiconductor layer having a single-quantum-well (SQW) structure or a multi-quantum-well (MQW) structure. When the active layer is an AlGaN-based semiconductor layer, a band gap energy can be adjusted within a range of lower and upper limits of band gap energies that can be taken by GaN and AlN respectively (about 3.4 eV and about 6.2 eV) by adjusting an AlN molar fraction (also referred to as an Al composition ratio). Thus, it is possible to obtain an ultraviolet light emitting element having a light emission wavelength of about 200 nm to about 365 nm. Specifically, when a forward current flows from the p-type nitride semiconductor layer to the n-type nitride semiconductor layer, light emission equivalent to the band gap energy occurs in the active layer.

Meanwhile, flip-chip mounting has been generally employed as a way of mounting a nitride semiconductor ultraviolet light emitting element (for example, see FIG. 4 or the like in Patent Document 1 below). In the flip-chip mounting, light emitted from an active layer is transmitted through an AlGaN-based nitride semiconductor, a sapphire substrate, or the like having a band gap energy greater than the active layer to be extracted from the element. For that reason, in the flip-chip mounting, the sapphire substrate faces upward, and p-side and n-side electrode surfaces formed on the upper surface side of a chip face downward. The electrode surfaces on the chip side are electrically and physically bonded via metal bumps formed on the electrode surfaces to electrode pads on a package component side such as a sub mount.

Generally, as disclosed in FIGS. 4, 6, and 7, or the like in Patent Document 2 below or FIGS. 2, 4, and 6, or the like in Patent document 3 below, the nitride semiconductor ultraviolet light emitting element is practically used in a state of being sealed with an ultraviolet-transparent resin such as a fluorine-based resin or a silicone resin. The sealing resin protects an ultraviolet light emitting element within the resin from the outside atmosphere, to prevent deterioration in the light emitting element caused by the entrance of water, oxidization, or the like. Furthermore, the sealing resin is sometimes provided as a refractive index difference mitigation material for improving light extraction efficiency by mitigating a light reflection loss caused by a refractive index difference between a light condensing lens and an ultraviolet light emitting element or a refractive index difference between a space to be irradiated with ultraviolet light and an ultraviolet light emitting element. The surface of the sealing resin may be formed into a light condensing curved surface such as a spherical surface to improve irradiation efficiency.

### PRIOR ART DOCUMENTS

### Patent Documents

PATENT DOCUMENT 1: WO 2014/178288
PATENT DOCUMENT 2: Japanese Patent Application Publication No. 2007-311707
PATENT DOCUMENT 3: U.S. Patent Application Publication No. 2006/0138443
PATENT DOCUMENT 4: Japanese Patent Application Publication No. 2006-348088

### Non-Patent Documents

NON-PATENT DOCUMENT 1: Kentaro Nagamatsu, et al., “High-efficiency AlGaN-based UV light emitting diode on laterally overgrown AlN”, Journal of Crystal Growth, 2008, 310, pp. 2326-2329
NON-PATENT DOCUMENT 2: Shigeaki Sumiya, et al., “AlGaN-Based Deep Ultraviolet Light emitting Diodes Grown on Epitaxial AlN/Sapphire Templates”, Japanese Journal of Applied Physics, Vol. 47, No. 1, 2008, pp. 43-46
NON-PATENT DOCUMENT 3: Kiho Yamada, et al., “Development of underfilling and encapsulation for deep-ultraviolet LEDs”, Applied Physics Express, 8, 012101, 2015

### SUMMARY OF THE INVENTION

### Problems to be Solved by the Invention

As described above, it has been proposed to use a fluorine-based resin, a silicone resin, and the like as a sealing resin for an ultraviolet light emitting element. However, it has been found that, if the silicone resin is exposed to a large amount of high energy ultraviolet light, deterioration in the silicone resin is prompted. In particular, there has been prompted lower wavelength and higher output of the ultraviolet light emitting element, and thus the deterioration in the sealing resin caused by exposure to the ultraviolet light tends to be accelerated. The heat generation is also increased by increase in consumption power associated with higher output, which disadvantageously also leads to the deterioration in the sealing resin.

While it has been known that a fluorine-based resin has excellent heat resistance and high ultraviolet resistance, a general fluororesin such as polytetrafluoroethylene is opaque. The fluorine-based resin has linear and rigid polymer chains and is easily crystallized. Consequently, there are a crystalline portion and an amorphous portion in a mixed manner in the fluororesin. Light is scattered at an interface between the crystalline portion and the amorphous portion, and thus the fluororesin is opaque.

For example, it is proposed in Patent Document 4 above that an amorphous fluororesin is used as a sealing resin of an ultraviolet light emitting element to improve the transparency of the amorphous fluororesin to ultraviolet light. Examples of the amorphous fluororesin include one with a fluororesin of a crystalline polymer copolymerized and made amorphous as a polymer alloy, a copolymer of perfluorodioxole (trade name Teflon AF (registered trademark) manufactured by du Pont) and a cyclopolymerized polymer of perfluorobutenyl vinyl ether (trade name CYTOP (registered trademark) manufactured by Asahi Glass Co., Ltd.). The latter fluororesin of the cyclopolymerized polymer has a cyclic structure on the main chain, and thus is easily amorphized. As a result, the fluororesin has high transparency.

Amorphous fluororesins are broadly classified into two types of a bonding amorphous fluororesin having a reactive functional group capable of bonding to a metal such as a carboxyl group, and a non-bonding amorphous fluororesin having a functional group that is hardly bonded to a metal such as a perfluoroalkyl group. The bonding amorphous fluororesin is used for a portion covering a surface of a base, on which a LED chip is mounted, and the LED chip, so that it is possible to improve the bondability between the base or the like and a fluororesin. In the present invention, the term “bonding” includes the meaning of having affinity with an interface of a metal or the like. Similarly, the term “non-bonding” includes the meaning of having non-affinity with an interface of a metal or the like, or having extremely low affinity.

Meanwhile, it has been reported in Patent Document 1 and Non-Patent Document 3 above that, in the case where a bonding amorphous fluororesin having a reactive functional group in which a terminal functional group is bondable to a metal is used for a portion covering a pad electrode of a nitride semiconductor ultraviolet light emitting element that emits deep ultraviolet light having a light emission center wavelength of 300 nm or less, the electrical characteristics of the ultraviolet light emitting element are deteriorated when an ultraviolet light emission operation is performed by applying a forward voltage between metal electrode wirings connected to a p-electrode and an n-electrode, respectively, of the ultraviolet light emitting element. Specifically, it has been confirmed that a resistant leakage current path is formed between the p-electrode and the n-electrode of the ultraviolet light emitting element. According to Patent Document 1 above, it is considered that, when the amorphous fluororesin is a bonding amorphous fluororesin, a reactive terminal functional group in the bonding amorphous fluororesin irradiated with high-energy deep ultraviolet light is separated and radicalized due to a photochemical reaction, and coordinate-bonded to metal atoms that form a pad electrode, so that the metal atoms are separated from the pad electrode. Furthermore, it is considered that an electric field is applied between pad electrodes during the light emission operation, and as a result, the metal atoms migrate to form a resistant leakage current path, so that a short-circuit occurs between the p-electrode and the n-electrode of the ultraviolet light emitting element.

Furthermore, it is reported in Non-Patent Document 3 above that, in the case where a bonding amorphous fluororesin is used and a stress by the light emission operation of deep ultraviolet light is continuously applied, the decomposition of the amorphous fluororesin is caused by a photochemical reaction, and air bubbles are generated between an amorphous fluororesin covering a metal electrode wiring on the base side and the metal electrode wiring.

In Patent Document 1 and Non-Patent Document 3 above, for a nitride semiconductor ultraviolet light emitting element that emits deep ultraviolet light, use of the non-bonding amorphous fluororesin is recommended in order to avoid the short circuit between the p-electrode and the n-electrode of the ultraviolet light emitting element caused by the photochemical reaction and the generation of the air bubbles between the amorphous fluororesin and the metal electrode wiring.

However, as described above, the non-bonding amorphous fluororesin is hardly bonded to a metal, and is further hardly bonded to the rear surface of a sapphire substrate that directly contacts with the non-bonding amorphous fluororesin during flip-chip mounting. That is, bonding provided by van der Waals force at an interface between the non-bonding amorphous fluororesin and the rear surface of the sapphire substrate is weak, so that when a repulsive force greater than the van der Waals force is generated at the interface by any factor, a part of the amorphous fluororesin is peeled off from the rear surface of the sapphire substrate, and it cannot deny the possibility of a void to be formed in the peeled portion. If, by any possibility, the void is formed on the rear surface of the sapphire substrate and a low refractive index gas such as air enters, the transmission of ultraviolet light from the sapphire substrate to the amorphous fluororesin side is inhibited, which may cause decreased extraction efficiency of the ultraviolet light to the outside of the element.

The present invention has been made in view of the above-described problems, and an object thereof is to provide an ultraviolet light emitting device having high quality and high reliability that prevents deterioration in electrical characteristics caused by a photochemical reaction of a non-bonding amorphous fluororesin, decomposition or the like of the amorphous fluororesin, and peeling off of the amorphous fluororesin.

### Means for Solving the Problem

The present inventors have conducted intensive studies, and have found that, the smaller the molecular weight of a non-bonding amorphous fluororesin is, the greater the surface tension is, and the surface tension can act as a repulsive force against the bonding provided by van der Waals force at an interface between the non-bonding amorphous fluororesin and the rear surface of a sapphire substrate. More specifically, the present inventors have found that, depending on the surface roughness of a sapphire substrate, when the weight average molecular weight of a non-bonding amorphous fluororesin is not equal to or greater than a certain value, that is, when the surface tension is not weak to a certain degree, the non-bonding amorphous fluororesin aggregates on the rear surface of the sapphire substrate and does not completely cover the entire rear surface of the sapphire substrate, leading to the present invention to be described later based on the novel finding.

In order to achieve the above object, the present invention provides an ultraviolet light emitting device comprising:

a base;

a nitride semiconductor ultraviolet light emitting element flip-chip mounted on the base; and

an amorphous fluororesin sealing the nitride semiconductor ultraviolet light emitting element,

wherein,

the nitride semiconductor ultraviolet light emitting element includes a sapphire substrate, a plurality of AlGaN-based semiconductor layers laminated on a surface of the sapphire substrate, an n-electrode including one or a plurality of metal layers, and a p-electrode including one or a plurality of metal layers,

a rear surface of the sapphire substrate is a polished surface having an epitaxial growth grade that is the same as an epitaxial growth grade on a surface side of the sapphire substrate, or a roughened surface having a surface roughness greater than a surface roughness of the polished surface and having an arithmetic average roughness Ra of 25 nm or more,

a structural unit of a polymer or copolymer constituting the amorphous fluororesin has a fluorine-containing aliphatic cyclic structure,

in the amorphous fluororesin, a terminal functional group of a polymer or copolymer constituting a first resin portion that is in direct contact with the nitride semiconductor ultraviolet light emitting element is a perfluoroalkyl group, and

when the rear surface of the sapphire substrate is the polished surface, the polymer or copolymer constituting the first resin portion has a weight average molecular weight of 230000 or more, and when the rear surface of the sapphire substrate is the roughened surface, the weight average molecular weight is 160,000 or more.

Furthermore, in order to achieve the above object, the present invention provides a method for manufacturing an ultraviolet light emitting device, the ultraviolet light emitting device comprising a base; a nitride semiconductor ultraviolet light emitting element flip-chip mounted on the base; and an amorphous fluororesin sealing the nitride semiconductor ultraviolet light emitting element,

wherein,

the nitride semiconductor ultraviolet light emitting element includes a sapphire substrate, a plurality of AlGaN-based semiconductor layers laminated on a surface of the sapphire substrate, an n-electrode including one or a plurality of metal layers, and a p-electrode including one or a plurality of metal layers,

a rear surface of the sapphire substrate is a polished surface having an epitaxial growth grade that is the same as an epitaxial growth grade on a surface side of the sapphire substrate, or a roughened surface having a surface roughness greater than a surface roughness of the polished surface and having an arithmetic average roughness Ra of 25 nm or more,

a step of forming a first resin portion that is in direct contact with the nitride semiconductor ultraviolet light emitting element in the amorphous fluororesin includes the steps of:
dissolving in a fluorine-containing solvent a first type amorphous fluororesin in which a structural unit of a polymer or copolymer constituting the amorphous fluororesin has a fluorine-containing aliphatic cyclic structure and a terminal functional group of the polymer or copolymer is a perfluoroalkyl group, to prepare a coating liquid;
applying the coating liquid so as to cover an exposed surface of each of the nitride semiconductor ultraviolet light emitting element and the base and to fill a gap part between the nitride semiconductor ultraviolet light emitting element and the base; and
heating the coating liquid to a boiling point or higher of the fluorine-containing solvent and evaporating the fluorine-containing solvent, to form a first resin layer that covers the exposed surface of each of the nitride semiconductor ultraviolet light emitting element and the base and fills the gap part between the nitride semiconductor ultraviolet light emitting element and the base,
when the rear surface of the sapphire substrate is the polished surface, the polymer or copolymer constituting the first type amorphous fluororesin has a weight average molecular weight of 230000 or more, and
when the rear surface of the sapphire substrate is the roughened surface, the weight average molecular weight is 160,000 or more.

In the present invention, an AlGaN-based semiconductor is a group-III nitride semiconductor that is based on a ternary (or binary) compound represented by the general formula: AlₓGa₁₋ₓN (x represents an AlN molar fraction, 0≤x≤1) and has a band gap energy equal to or greater than a band gap energy of GaN (x=0) (about 3.4 eV). As long as conditions regarding the band gap energy are satisfied, the semiconductor may contain a trace amount of In, P, As, or the like.

In the ultraviolet light emitting device having the above feature and the method for manufacturing the ultraviolet light emitting device having the above feature, first, the non-bonding amorphous fluororesin in which the terminal functional group is the perfluoroalkyl group is used as the first resin portion that is in direct contact with the nitride semiconductor ultraviolet light emitting element for sealing, so that the deterioration in electrical characteristics which is associated with the ultraviolet light emission operation and caused by the photochemical reaction in the case of using the bonding amorphous fluororesin, the decomposition of the amorphous fluororesin, or the like described above can be prevented.

The deterioration in electrical characteristics which is associated with the ultraviolet light emission operation and caused by the photochemical reaction in the case of using the bonding amorphous fluororesin, the decomposition of the amorphous fluororesin, or the like described above remarkably occurs when the nitride semiconductor ultraviolet light emitting element has a light emission center wavelength of 290 nm or less, so that the ultraviolet light emitting device or the method for manufacturing the ultraviolet light emitting device having the above feature is particularly effective and suitable for the ultraviolet light emitting device in which the nitride semiconductor ultraviolet light emitting element has a light emission center wavelength of 290 nm or less, or the method for manufacturing the ultraviolet light emitting device.

Furthermore, when the rear surface of the sapphire substrate is the polished surface having an epitaxial growth grade, the polymer or copolymer constituting the first resin portion has a weight average molecular weight of 230000 or more. When the rear surface of the sapphire substrate is the roughened surface having a surface roughness greater than a surface roughness of the polished surface and having an arithmetic average roughness Ra of 25 nm or more, the weight average molecular weight is 160,000 or more and it is equal to or greater than a predetermined molecular weight depending on the surface roughness of the rear surface of the sapphire substrate with which the first resin portion is in direct contact. Accordingly, the surface tension as a repulsive force against the bonding provided by van der Waals force at an interface between the rear surface of the sapphire substrate having the surface roughness and the first resin portion can be suppressed. That is, the bonding provided by the van der Waals force at the interface between the rear surface of the sapphire substrate and the first resin portion becomes weaker as the surface roughness becomes smaller (as the surface is more highly polished), and becomes strong as the surface roughness is increased (as the surface is rougher). However, the surface tension of the first resin portion as the repulsive force against the bonding force at the interface corresponding to the degree of the surface roughness can be suppressed by adjusting the weight average molecular weight of the first resin portion, so that it is possible to avoid the disadvantage that the non-bonding amorphous fluororesin of the first resin portion aggregates on the rear surface of the sapphire substrate to incompletely cover the entire rear surface of the sapphire substrate.

Furthermore, it is preferable that, in the ultraviolet light emitting device having the above feature and the method for manufacturing the ultraviolet light emitting device having the above feature, the rear surface of the sapphire substrate is a roughened surface having a surface roughness greater than a surface roughness of the polished surface and having an arithmetic average roughness Ra of 25 nm or more, and the roughened surface is a concavoconvex processed surface formed by uniformly dispersing minute protrusions or depressions on the entire rear surface, or a non-polished surface. According to the suitable aspect, a contact area between the rear surface of the sapphire substrate and the first resin portion is greater than a contact area in the case where the rear surface of the sapphire substrate is a polished surface having an epitaxial growth grade, so that the bonding provided by the van der Waals force at the interface between the sapphire substrate and the first resin portion is increased, and influence of the surface tension of the first resin portion can be mitigated, and this makes it possible to reduce the lower limit value of the weight average molecular weight available for the first resin portion. In the case where the weight average molecular weight of the first resin portion is the same, it is more satisfactorily possible to avoid the disadvantage that the non-bonding amorphous fluororesin of the first resin portion aggregates on the rear surface of the sapphire substrate to incompletely cover the entire rear surface of the sapphire substrate, when the rear surface of the sapphire substrate is a roughened surface having an arithmetic average roughness Ra of 25 nm or more as compared with the case of the polished surface.

Furthermore, in the ultraviolet light emitting device having the above feature and the method for manufacturing the ultraviolet light emitting device having the above feature, it is preferable that the terminal functional group is CF₃.

Furthermore, in the ultraviolet light emitting device having the above feature and the method for manufacturing the ultraviolet light emitting device having the above feature, it is preferable that the nitride semiconductor ultraviolet light emitting element has a light emission center wavelength of 290 nm or less.

Furthermore, in the method for manufacturing the ultraviolet light emitting device having the above feature, it is preferable that the fluorine-containing solvent is an aprotic fluorine-containing solvent.

### Effect of the Invention

The ultraviolet light emitting device having the above feature and the method for manufacturing the ultraviolet light emitting device having the above feature can provide an ultraviolet light emitting device having high quality and high reliability that prevents deterioration in electrical characteristics caused by a photochemical reaction of a non-bonding amorphous fluororesin, decomposition or the like of the amorphous fluororesin, and peeling off of the amorphous fluororesin.

### BRIEF DESCRIPTION OF THE DRAWINGS

FIG. 1 is a cross-sectional view schematically showing an example of an element structure in one embodiment of a nitride semiconductor ultraviolet light emitting element according to the present invention.

FIG. 2 is a plan view schematically showing the example of the element structure in one embodiment of the nitride semiconductor ultraviolet light emitting element according to the present invention.

FIG. 3 is a cross-sectional view schematically showing an example of a cross-sectional structure in one embodiment of an ultraviolet light emitting device according to the present invention.

FIGS. 4A and 4B are a plan view and a cross-sectional view schematically showing a plane shape and cross-sectional shape of a submount used in the ultraviolet light emitting device shown in FIG. 3.

FIG. 5 is a photograph of a sample after resin sealing showing the result of Evaluation Experiment 1 taken from an upper surface.

FIG. 6 is an SEM photograph of a moth-eye structure formed on the rear surface of a sapphire substrate of a nitride semiconductor ultraviolet light emitting element used in Evaluation Experiment 2 in top view.

FIG. 7 is a photograph of a sample after resin sealing showing the result of Evaluation Experiment 2 taken from an upper surface.

FIG. 8 is a photograph of a sample after resin sealing showing the result of Evaluation Experiment 3 taken from an upper surface.

FIG. 9 is an SEM photograph of a cross section of a sample after resin sealing showing the result of Evaluation Experiment 4.

### DESCRIPTION OF EMBODIMENT

Embodiments of an ultraviolet light emitting device and a method for manufacturing the same according to the present invention will be described with reference to the drawings. In the drawings used in the following descriptions, the substance of the invention is schematically shown while the principal part is partially emphasized for easy understanding of the descriptions, and therefore the dimensional ratio of each part is not always identical to that of each of an actual element and a component to be used. Hereinafter, an ultraviolet light emitting device according to the present invention is appropriately referred to as “the present light emitting device”. A method for manufacturing the same is referred to as “the present manufacturing method”. A nitride semiconductor ultraviolet light emitting element used in the present light emitting device is referred to as “the present light emitting element”. Furthermore, in the following description, it is assumed that the present light emitting element is a light emitting diode.

[Element Structure of Present Light Emitting Element]

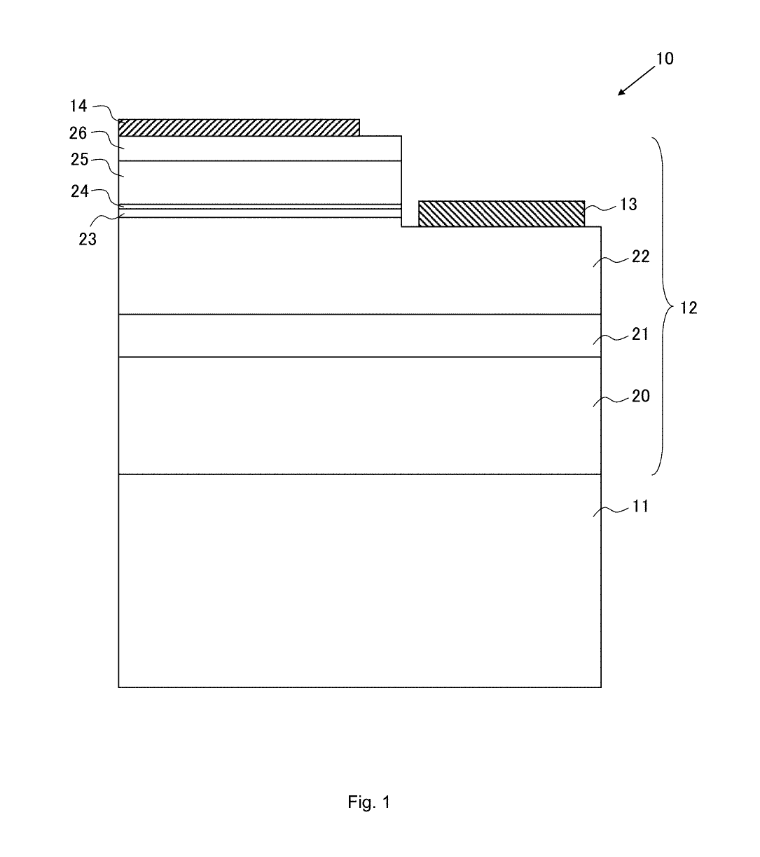

First, the element structure of the present light emitting element 10 will be described. As shown in FIG. 1, in the basic element structure of the present light emitting element 10, a semiconductor laminated part 12 including a plurality of AlGaN-based semiconductor layers, an n-electrode 13, and a p-electrode 14 are provided on the surface of a sapphire substrate 11. It is previously assumed that the light emitting element 10 is flip-chip mounted, and light emitted from the semiconductor laminated part 12 is extracted to the outside from the rear surface side of the sapphire substrate 11.

As an example, in the semiconductor laminated part 12, an AlN layer 20, an AlGaN layer 21, an n-type clad layer 22 made of n-type AlGaN, an active layer 23, an electron blocking layer 24 made of p-type AlGaN, a p-type clad layer 25 made of p-type AlGaN, and a p-type contact layer 26 made of p-type GaN are laminated in order from the sapphire substrate 11 side. A light emitting diode structure is formed by from the n-type clad layer 22 to the p-type contact layer 26. The sapphire substrate 11, the AlN layer 20, and the AlGaN layer 21 function as a template for forming the light emitting diode structure thereon. The active layer 23, the electron blocking layer 24, the p-type clad layer 25, and the p-type contact layer 26 located above the n-type clad layer 22 are partially removed by reactive ion etching or the like until a part of the surface of the n-type clad layer 22 is exposed. The semiconductor layer from the active layer 23 to the p-type contact layer 26 located above the exposed surface of the n-type clad layer 22 after the removal is conveniently referred to as a “mesa portion”. As an example, the active layer 23 has a single-layer quantum well structure including an n-type AlGaN barrier layer and an AlGaN or GaN well layer. The active layer 23 may have a double-hetero junction structure sandwiched between n-type and p-type AlGaN layers having a high AlN molar fraction as a lower layer and an upper layer. The active layer 23 may have a multiple quantum well structure provided by the multi-layering of the single-layer quantum well structure.

Each AlGaN layer is formed by a well-known epitaxial growth method such as a metalorganic vapor phase epitaxy (MOVPE) method or a molecular beam epitaxy (MBE) method. For example, Si is used as a donor impurity of an n-type layer. For example, Mg is used as an acceptor impurity of a p-type layer.

For example, an n-electrode 13 made of Ti/Al/Ti/Au is formed on the exposed surface of the n-type clad layer 22. For example, a p-electrode 14 made of Ni/Au is formed on the surface of the p-type contact layer 26. The number and material of metal layers constituting the n-electrode 13 and the p-electrode 14 are not limited to the above-exemplified number and material of the layers.

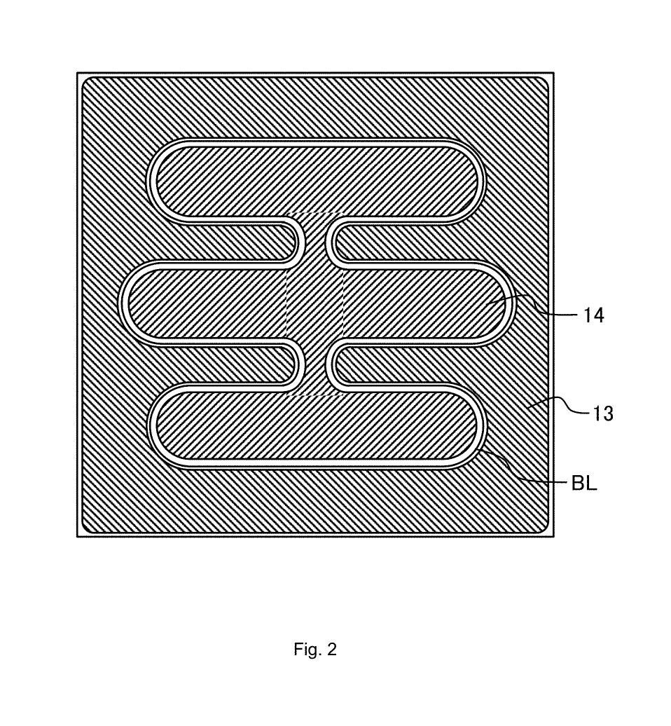

In the present embodiment, as exemplified in FIG. 2, the chip shape of the present light emitting element 10 in plan view is a square shape. In the outer peripheral portion of the chip, the surface of the n-type clad layer 22 is exposed so as to surround the mesa portion located at the center and having a comb plane shape. Furthermore, a configuration example is assumed, in which the n-electrode 13 is annularly formed on the exposed surface of the n-type clad layer 22 so as to surround the mesa portion, and the p-electrode 14 is formed at the top part of the mesa portion. In FIG. 2, hatched portions are the n-electrode 13 and p-electrode 14. A boundary line BL between the mesa portion and the exposed surface of the n-type clad layer 22 is shown for reference.

In the present embodiment, as shown in FIG. 2, a configuration example is assumed, in which the exposed area of the n-electrode 13 is widened at four corners of the chip, and in flip-chip mounting described later, at the four corners, the n-electrode 13 is physically and electrically connected to a corresponding electrode pad on a submount via a bonding material. The chip shape of the present light emitting element 10 in plan view, the plane shape of the mesa portion, the number and formation position of the n-electrodes 13, and the number and formation position of the p-electrodes 14 are not limited to the shapes, numbers, and forming positions exemplified in FIG. 2. In the present embodiment, it is assumed that the size of one side of the chip is about 0.8 mm to 1.5 mm, but the size of the chip is not limited to the range.

In the present light emitting element 10, the semiconductor laminated part 12, the n-electrode 13, and the p-electrode 14 formed on the surface side of the sapphire substrate 11 are not limited to the configurations and structures exemplified above, and various known configurations and structures may be employed. The light emitting element 10 may include elements other than the semiconductor laminated part 12, the n-electrode 13, and the p-electrode 14, for example, a protective film or the like. Accordingly, the detailed descriptions of the film thickness or the like of each of the AlGaN layers 20 to 26 and each of the electrodes 13 and 14 will be omitted. The AlN molar fraction of each of the AlGaN layers 21 to 25 is appropriately set such that the present light emitting element 10 has a light emission center wavelength of about 350 nm or less, and light is emitted through the sapphire substrate 11.

Each of the AlGaN layers 20 to 26 of the semiconductor laminated part 12 is required to be sequentially grown on the surface side of the sapphire substrate 11 by a well-known epitaxial growth method, so that the surface of the sapphire substrate 11 has a polished surface having an epitaxial growth grade in a wafer state before the semiconductor laminated part 12 is formed. As the specification value of the surface roughness of the polished surface having an epitaxial growth grade, for example, the arithmetic average roughness Ra is defined to be 0.3 nm or less or 1 nm or less in a plurality of companies supplying sapphire substrates to the market. In the present embodiment, as the sapphire substrate 11, a sapphire substrate is used, which has a polished surface having an epitaxial growth grade and having an arithmetic average roughness Ra of 0.3 nm or less.

Meanwhile, it is not necessary to grow a semiconductor layer on the rear surface side of the sapphire substrate 11, so that the rear surface side of the sapphire substrate 11 does not necessarily have a polished surface having the same epitaxial growth grade as that on the surface side. However, in order to determine the quality of the light output from the present light emitting element 10 in a wafer state before dicing, it is preferable that the rear surface side also has a polished surface having the same epitaxial growth grade as that on the surface. When the rear surface of the wafer has a roughened surface such as a non-polished surface, the present light emitting element 10 is not sealed with a resin when determining the quality of the light output in the wafer state, and light emitted from the rear surface of the sapphire substrate is scattered on the rear surface in a roughened surface state to cause the emission direction of the light to be enlarged. The decreased light reception amount of the light output to be determined may disadvantageously cause deterioration of accuracy for determining the quality of the light output. If the deterioration of accuracy for determining the quality of the light output is within an allowable range, it is preferable that the rear surface side of the sapphire substrate 11 has a roughened surface from the viewpoint of adhesiveness to a sealing resin.

Furthermore, the light extraction efficiency from the rear surface side of the sapphire substrate 11 is known to be improved by adopting a minute concavoconvex structure such as a moth-eye structure or a photonic crystal structure in which minute protrusions each having a cone shape or the like are two-dimensionally and evenly dispersed and arranged on the rear surface side of the sapphire substrate 11. Therefore, also in the present light emitting element 10, the concavoconvex processed surface on which a minute concavoconvex structure such as a moth-eye structure is provided may be formed on the rear surface side of the sapphire substrate 11. It is preferable that the minute concavoconvex structure is formed by processing the rear surface side in the wafer state. The minute concavoconvex structure can be realized by, for example, etching the rear surface of the sapphire substrate 11 on which a resist having a predetermined shape is formed with use of a well-known nanoimprint technique.

As described above, in the present embodiment, it is assumed that the rear surface side of the sapphire substrate 11 has any of (1) a polished surface having an epitaxial growth grade, or (2) a roughened surface having a surface roughness greater than that of the polished surface and having an arithmetic average roughness Ra of 25 nm or more. It is assumed that (2) the roughened surface is any of (2A) a non-polished surface, (2B) a concavoconvex processed surface provided with a minute concavoconvex structure such as a moth-eye structure and having an arithmetic average roughness Ra of 25 nm or more, (2C) a roughened surface obtained by roughening a polished surface such that the polished surface has an arithmetic average roughness Ra of 25 nm or more, or (2D) an incompletely polished surface obtained by polishing a non-polished surface to such a degree that the incompletely polished surface does not have an arithmetic average roughness Ra of less than 25 nm. The standard specification value of the arithmetic average roughness Ra in the non-polished surface of the sapphire substrate is, for example, 1.2 μm or less, which is about 0.2 μm as measured by the present inventors using a laser microscope. Therefore, the non-polished surface of the sapphire substrate satisfies the condition that the non-polished surface is a roughened surface having an arithmetic average roughness Ra of 25 nm or more. Furthermore, when the cross-sectional shape of the minute protrusion or minute depression can be approximated by an isosceles triangle in the case of the concavoconvex processed surface provided with a minute concavoconvex structure, the height of the minute protrusion or the depth of the minute depression is set to 100 nm or more, and thus the condition that the concavoconvex processed surface is a roughened surface having an arithmetic average roughness Ra of 25 nm or more is satisfied.

As described later, the present light emitting device 1 is characterized in that, in a configuration in which the present light emitting element 10 placed on a base such as a submount 30 by a flip-chip mounting method is covered with a non-bonding amorphous fluororesin for sealing, the weight average molecular weight of the non-bonding amorphous fluororesin is adjusted to a predetermined molecular weight or more corresponding to the surface property of the rear surface of the sapphire substrate 11 with which the non-bonding amorphous fluororesin is in direct contact (a polished surface having an epitaxial growth grade or a roughened surface having an arithmetic average roughness Ra of 25 nm or more). Therefore, the semiconductor laminated part 12, the n-electrode 13, and the p-electrode 14 formed on the surface of the sapphire substrate 11 are not the main objects of the present invention, and various modified examples are considered as a specific element structure. The semiconductor laminated part 12, the n-electrode 13, and the p-electrode 14 can be manufactured by a well-known manufacturing method, so that the detailed description of the method for manufacturing the present light emitting element 10 will be omitted.

[Configuration Example of the Present Light Emitting Device]

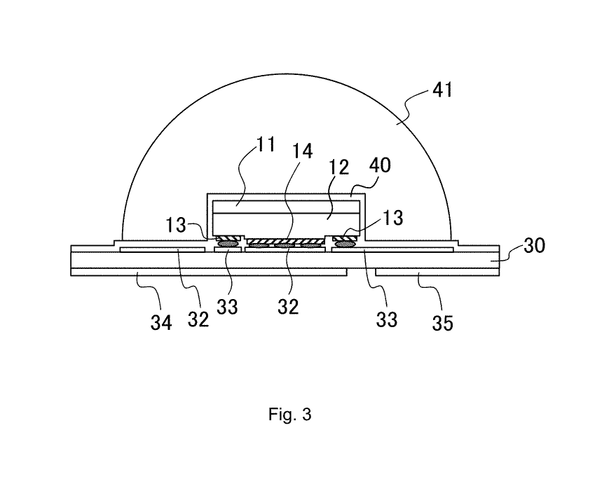

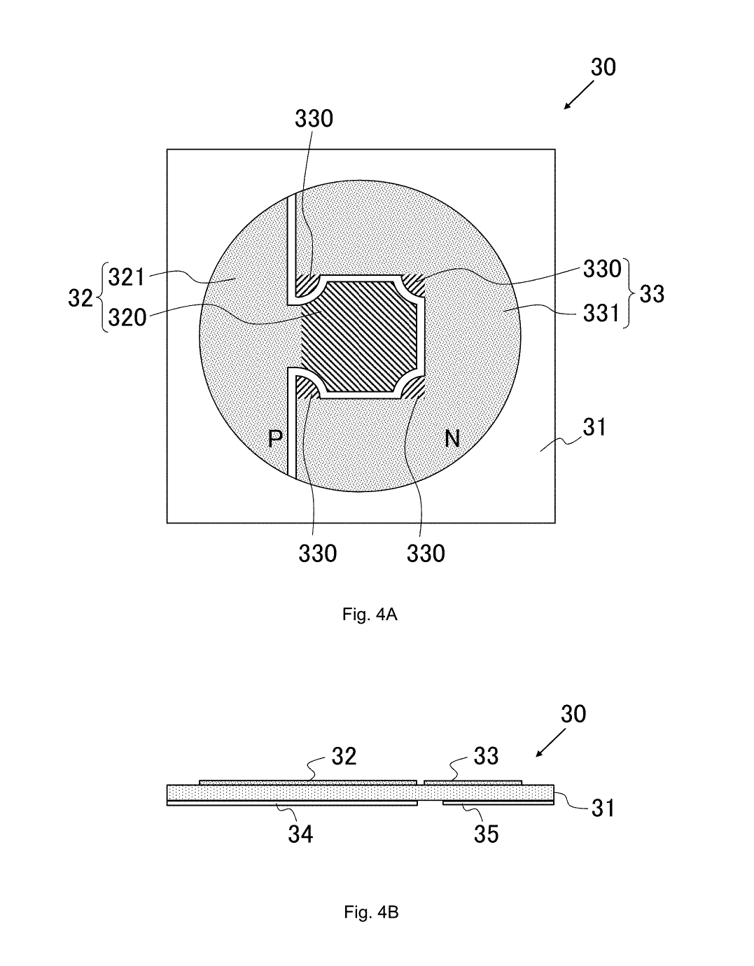

Next, the present light emitting device 1 obtained by placing the present light emitting element 10 on the submount 30 that is a base for flip-chip mounting by a flip-chip mounting method will be described with reference to FIGS. 3, 4A and 4B. FIG. 3 schematically shows the schematic cross-sectional structure of one configuration example of the present light emitting device 1. In FIG. 3, the present light emitting element 10 is illustrated with the rear surface side of the sapphire substrate 11 facing upward. In the following description with reference to FIG. 3, the upward direction is a direction toward the present light emitting element 10 side with reference to the placement surface of the submount 30.

FIG. 4A is a plan view showing the plane shape of the submount 30. FIG. 4B is a cross-sectional view showing the shape of a cross-section which passes through the center of the submount 30 in the plan view (FIG. 4A) and is vertical to the surface of the submount 30. The length of a side of the submount 30 is not limited to a particular value as long as there is room to form a sealing resin around the present light emitting element 10 mounted on the submount 30. As an example, the length of a side of the submount 30, which has a square plane shape, is preferably about 1.5 to 2 times or more greater than the chip size (the length of a side) of the present light emitting element 10 to be mounted, which has also a square plane shape. The plane shape of the submount 30 is not limited to a square shape.

The submount 30 includes a plate-like base material 31 made of an insulating material such as an insulating ceramic. The submount 30 is configured such that a first metal electrode wiring 32 on the anode side and a second metal electrode wiring 33 on the cathode are each formed on the surface side of the base material 31, and lead terminals 34 and 35 are formed on the rear surface side of the base material 31. The first and second metal electrode wirings 32 and 33 on the surface side of the base material 31 are respectively connected to the lead terminals 34 and 35 on the rear surface side of the base material 31 via penetration electrodes (not shown) provided on the base material 31. When the submount 30 is placed on other wiring boards or the like, metals wirings on the wiring boards are electrically connected to the lead terminals 34 and 35. The lead terminals 34 and 35 cover substantially the entire rear surface of the base material 31 to function as a heat sink.

As shown in FIGS. 4A and 4B, the first and second metal electrode wirings 32 and 33 are formed on the center portion of the base material 31 where the light emitting element 10 is mounted and a surrounding portion thereof. The first and second metal electrode wirings 32 and 33 are disposed so as to be spaced apart from each other, and are electrically separated from each other. The first metal electrode wiring 32 includes a first electrode pad 320 and a first wiring part 321 connected to the first electrode pad 320. The second metal electrode wiring 33 includes four second electrode pads 330 and a second wiring part 331 connected to the second electrode pads 330. The first electrode pad 320 has a plane shape slightly greater than the outer frame of the comb plane shape of the p-electrode 14 of the present light emitting element 10 (the outer periphery of a shape assuming that a mesa portion is also present in a comb shaped concave portion), and is located at the center of the central portion of the base material 31. In the case where the present light emitting element 10 is disposed such that the p-electrode 14 of light emitting element 10 opposes the first electrode pad 320, the plane shape, number, and arrangement of the second electrode pads 330 are set so that the four corners of the chip of the n-electrode 13 in which the exposed area is wide oppose the four second electrode pads 330. In FIG. 4A, the first electrode pad 320 and the second electrode pads 330 are hatched. The plane shapes of the first and second metal electrode wirings 32 and 33 are not limited to the shapes shown in FIG. 4A, and can be variously modified as long as the first and second metal electrode wirings 32 and 33 have a plane shape such that the p-electrode 14 can oppose the first electrode pad 320 and the four corners of the n-electrode 13 can oppose the second electrode pads 330.

In the present embodiment, the base material 31 of the submount 30 is composed of an insulating material such as aluminum nitride (AlN) that is not deteriorated by being exposed to ultraviolet light. While the base material 31 is preferably composed of AlN in view of heat dissipation, the base material 31 may be composed of silicon carbide (SiC), silicon nitride (SiN), or boron nitride (BN), or may be ceramics such as alumina (Al₂O₃). The base material 31 may be composed of not only a solid insulating material of the insulating material but also a sintered body obtained by tightly bonding particles of the insulating material using silica glass as a binder. Furthermore, the base material 31 may be composed of a diamond-like carbon (DLC) thin film, an industrial diamond thin film, or the like.

In the case of the configuration in which the lead terminals 34 and 35 are not provided on the rear surface side of the base material 31 in the submount 30, the base material 31 is composed of not only the insulating material, and may have a laminated structure of a metal film (for example, Cu or Al) and an insulating layer composed of the above insulating material.

As an example, the first and second metal electrode wirings 32 and 33 include a thick copper-plated film and a single or multi-layer surface metal film that covers the surface (the upper surface and the side wall surface) of the thick plated film. The outermost layer of the surface metal film is composed of a metal having ionization tendency smaller than that of copper constituting the thick plated film (for example, gold (Au), platinum group metals (Ru, Rh, Pd, Os, Ir, Pt, or two or more alloys thereof), or alloys of gold and platinum group metals).

The present light emitting element 10 is placed and fixed on the central portion of the base material 31 in the following state. The n-electrode 13 and the p-electrode 14 face downward. The p-electrode 14 and the first electrode pad 320 face each other, and are electrically and physically connected to each other via gold bumps or the like (bonding materials). The four corners of the n-electrode 13 and the four second electrode pads 330 face one another, and are electrically and physically connected to one another via gold bumps or the like. As shown in FIG. 3, the present light emitting element 10 mounted on the submount 30 is sealed with a sealing resin 40. Specifically, the upper and side surfaces of the present light emitting element 10 and the upper surface of the submount 30 (the upper and side surfaces of the first and second metal electrode wirings 32 and 33, the surface of the base material 31 exposed between the first and second metal electrode wirings 32 and 33) are covered with the sealing resin 40. Furthermore, a gap part between the submount 30 and the present light emitting element 10 is filled with the sealing resin 40.

In the present embodiment, as shown in FIG. 3, the upper surface of the sealing resin 40 is, as an example, covered with a light condensing lens 41 made of the same fluorocarbon resin as the sealing resin 40. The lens 41 is not limited to be made of a fluororesin, and may be made of other materials having ultraviolet transparency adaptable to the light emission wavelength of the present light emitting element 10. The lens 41 is preferably made of a material having a small refractive index difference between the material and the sealing resin 40, and a quartz glass lens may be used. The lens 41 may be, in addition to a light condensing lens, a lens that diffuses light depending on intended use, and the lens 41 is not necessarily provided.

In the present embodiment, as the sealing resin 40, a non-bonding amorphous fluororesin having excellent heat resistance, ultraviolet resistance, and ultraviolet transparency is used. As described above, examples of the amorphous fluororesin include one with a fluororesin of a crystalline polymer copolymerized and made amorphous as a polymer alloy, a copolymer of perfluorodioxole (trade name Teflon AF (registered trademark) manufactured by du Pont) and a cyclopolymerized polymer of perfluorobutenyl vinyl ether (trade name CYTOP (registered trademark) manufactured by Asahi Glass Co., Ltd.). In the present embodiment, as an example, a non-bonding amorphous fluororesin is used, in which a structural unit constituting a polymer or copolymer has a fluorine-containing aliphatic cyclic structure, and a terminal functional group is a perfluoroalkyl group such as CF₃. The perfluoroalkyl group is hardly bonded to a metal or the like. That is, the non-bonding amorphous fluororesin does not have a reactive terminal functional group capable of bonding to a metal. Meanwhile, the bonding amorphous fluororesin has a reactive functional group that can be bonded to a metal as a terminal functional group even if the structural unit constituting the polymer or copolymer has the same fluorine-containing aliphatic cyclic structure, which is different from the non-bonding amorphous fluororesin. The reactive functional group is, as an example, a carboxyl group (COOH) or an ester group (COOR), where R represents an alkyl group.

The structural unit having the fluorine-containing aliphatic cyclic structure is preferably a unit based on a cyclic fluorine-containing monomer (hereinafter, “unit A”) or a unit formed by cyclopolymerization of diene fluorine-containing monomers (hereinafter, “unit B”). The composition and structure of the amorphous fluororesin are not the subject of the invention of the present application, and thus detailed descriptions of the unit A and the unit B will be omitted. For reference, the unit A and the unit B are described in detail in paragraphs [0031] to [0058] of Patent Document 1 by the same applicant as that of the present application.

Generally, the non-bonding amorphous fluororesin in which the structural unit constituting the polymer or copolymer has the fluorine-containing aliphatic cyclic structure and the terminal functional group is a perfluoroalkyl group such as CF₃ preferably has a weight average molecular weight of 3,000 to 1,000,000, more preferably 10,000 to 300,000, and still more preferably 100,000 to 250,000 (see, for example, the above Patent Document 1).

However, in the present embodiment, the non-bonding amorphous fluororesin used as the sealing resin 40 is prepared such that the first resin portion that is in direct contact with the exposed surface of the present light emitting element 10 (the rear and side surfaces of the sapphire substrate 11, the outermost surface (the exposed surfaces of the n-electrode 13 and p-electrode 14, or the like) and side surface of the semiconductor laminated part 12) has a weight average molecular weight of a predetermined molecular weight or more corresponding to the surface property of the rear surface of the sapphire substrate 11 (the polished surface having an epitaxial growth grade or the roughened surface having an arithmetic average roughness Ra of 25 nm or more). Specifically, when the rear surface of the sapphire substrate 11 has a polished surface having the same epitaxial growth grade as that of the surface side, the non-bonding amorphous fluororesin to be used is prepared such that the weight average molecular weight of at least the first resin portion is 230000 or more. When the rear surface of the sapphire substrate 11 has a roughened surface having an arithmetic average roughness Ra of 25 nm or more, the non-bonding amorphous fluororesin to be used is prepared such that the weight average molecular weight of at least the first resin portion is 160,000 or more. The limit (the above lower limit value) on the weight average molecular weight of the first resin portion is set based on experimental results from verification of a relationship to be shown below. The smaller the weight average molecular weight of the non-bonding amorphous fluororesin is, the greater the surface tension is. The surface tension acts as a repulsive force against the bonding provided by van der Waals force at an interface between the non-bonding amorphous fluororesin and the rear surface of the sapphire substrate, which causes the first resin portion to be apt to aggregate on the rear surface of the sapphire substrate, that is, wettability is deteriorated. Therefore, if the bonding strength at the interface between the non-bonding amorphous fluororesin and the rear surface of the sapphire substrate is the same, the first resin portion is more likely to completely cover the entire rear surface of the sapphire substrate as the weight average molecular weight of the first resin portion is increased. If the weight average molecular weight of the first resin portion is the same, the first resin portion is more likely to completely cover the entire rear surface of the sapphire substrate as the bonding force at the interface is increased. The bonding force at the interface changes depending on the surface roughness of the rear surface of the sapphire substrate, and the bonding force with the polished surface having an epitaxial growth grade is smaller than the bonding force with the roughened surface having an arithmetic average roughness Ra of 25 nm or more.

The non-bonding amorphous fluororesin, also including the first resin portion, used as the sealing resin 40 has a weight average molecular weight of preferably 1,000,000 or less, and more preferably 300,000 or less or 250,000 or less. For example, a non-bonding amorphous fluororesin having a weight average molecular weight within a range of 230,000 to 1,000,000 can be used in common regardless of the surface property of the rear surface of the sapphire substrate 11.

It is very difficult to estimate the molecular weight of the non-bonding amorphous fluororesin, but the weight average molecular weight can be estimated by converting, for example, according to melt viscosity or intrinsic viscosity. In the present embodiment, the weight average molecular weight is used as the average molecular weight of the non-bonding amorphous fluororesin, and the number average molecular weight is not estimated. Therefore, the molecular weight dispersion of the non-bonding amorphous fluororesin is not specified.

As a cyclopolymerization method, homopolymerization method, and copolymerization method of the monomers, known methods disclosed in, for example, Japanese Unexamined Patent Publication No. H4-189880 or the like can be applied. The weight average molecular weight of the above non-bonding amorphous fluororesin can be controlled in the above suitable range by adjusting the concentration of the monomer during the polymerization (cyclopolymerization, homopolymerization, copolymerization) of the monomer, adjusting the concentration of an initiator, and adding an additive transfer agent, or the like.

As terminal functional groups of the amorphous fluororesin after the polymerization treatment, the above-described reactive terminal functional groups and other unstable functional groups may be formed. Accordingly, by bringing a fluorine gas into contact with the amorphous fluororesin after the polymerization treatment using the known method disclosed in, for example, Japanese Unexamined Patent Publication No. H11-152310 or the like, these reactive terminal functional groups and unstable terminal functional groups are replaced by CF₃ that is a nonreactive functional group. This provides the non-bonding amorphous fluororesin to be used in the present light emitting device 1.

Examples of commercially available products of the non-bonding amorphous fluororesin include CYTOP (manufactured by Asahi Glass Co., Ltd.) and the like. CYTOP having a CF₃ terminal functional group is a copolymer of the unit B represented by the following Chemical Formula 1.

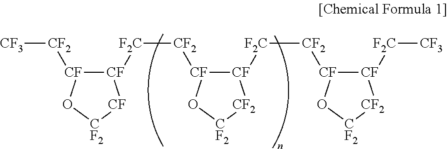

[Method for Manufacturing the Present Light Emitting Device]

Next, a method for manufacturing the present light emitting device will be described.

First, a diced bare chip of the present light emitting element 10 is fixed on the first and second metal electrode wirings 32 and 33 of the submount 30 by well-known flip-chip mounting. Specifically, the p-electrode 14 and the first metal electrode wiring 32 are physically and electrically connected to each other via a gold bump or the like, and the n-electrode 13 and the second metal electrode wiring 33 are physically and electrically connected to each other via a gold bump or the like (Step 1).

Subsequently, a coating liquid is prepared by dissolving a non-bonding amorphous fluororesin in a fluorine-containing solvent, and preferably an aprotic fluorine-containing solvent (Step 2). As described above, the non-bonding amorphous fluororesin to be used is prepared so as to have a predetermined molecular weight or more corresponding to the surface property of the rear surface of the sapphire substrate 11 (the polished surface having an epitaxial growth grade or the roughened surface having an arithmetic average roughness Ra of 25 nm or more). For example, a non-bonding amorphous fluororesin can be suitably used, which has a weight average molecular weight of 160,000 or 230,000 or more and 1,000,000 or less, and more preferably 300,000 or less or 250,000 or less.

Subsequently, the coating liquid prepared in Step 2 is injected onto the submount 30 and the present light emitting element 10 using a Teflon needle having good peelability or the like, and then the solvent is evaporated while the coating liquid is gradually heated. As a result, the first resin portion of the sealing resin 40 as the non-bonding amorphous fluororesin is formed on the upper and side surfaces of the present light emitting element 10, the upper surface of the submount 30 (the upper and side surfaces of the first and second metal electrode wirings 32 and 33, the surface of the base material 31 exposed between the first and second metal electrode wirings 32 and 33), and the gap part between the submount 30 and the present light emitting element 10 (Step 3). When the solvent is evaporated in Step 3, the solvent is gradually heated from a low-temperature range equal to or lower than the boiling temperature of the solvent (for example, about room temperature) to a high-temperature range equal to or higher than the boiling point of the solvent (for example, about 200° C.) to be evaporated without remaining air bubbles in the sealing resin 40.

When the non-bonding amorphous fluororesin used in Step 2 has a weight average molecular weight of 230,000 or more, irrespective of the surface property of the rear surface of the sapphire substrate 11 (the polished surface having an epitaxial growth grade or the roughened surface having an arithmetic average roughness Ra of 25 nm or more), the following disadvantage can be avoided: the non-bonding amorphous fluororesin aggregates on the rear surface of the sapphire substrate 11 due to its surface tension during the formation of the first resin portion in Step 3, and the rear surface of the sapphire substrate 11 is not completely covered with the first resin portion.

Subsequently, the sealing resin 40 is softened by heating in a temperature range equal to or lower than a temperature (about 350° C.) at which the decomposition of the non-bonding amorphous fluororesin starts, for example, in a temperature range from 150° C. to 300° C., and more preferably in a temperature range from 200° C. to 300° C., and the sealing resin 40 on the upper surface of the present light emitting element 10 is pressed toward the present light emitting element 10 side (Step 4).

Subsequently, a lens 41 made of the same non-bonding amorphous fluororesin as the sealing resin 40 is formed on the upper part of the sealing resin 40 so as to cover the present light emitting element 10 by, for example, injection molding, transfer molding, compression molding, or the like (Step 5). As a mold for each of the above moldings, a metal mold, a silicone resin mold, or a combination thereof can be used.

The heating and pressing treatments in Step 4 may be performed simultaneously with the formation of the lens 41 in Step 5. Alternatively, only the heat treatment may be performed in Step 4, and the pressing treatment may be performed during the formation of the lens 41 in Step 5. Instead of forming the lens 41 in Step 5, a second resin portion that does not have a lens shape may be formed on the upper side of the first resin portion. Furthermore, Step 4 and Step 5 do not need to be necessarily performed.

[Regarding Relationship Between Weight Average Molecular Weight of Non-Bonding Amorphous Fluororesin and Surface Property of Rear Surface of Sapphire Substrate]

The specific feature of the present light emitting device 1 is that, in the configuration in which the present light emitting element 10 placed on the base such as the submount 30 by the flip-chip mounting method is covered with the non-bonding amorphous fluororesin for sealing, the weight average molecular weight of the non-bonding amorphous fluororesin is adjusted to a predetermined molecular weight or more corresponding to the surface property of the rear surface of the sapphire substrate 11 with which the non-bonding amorphous fluororesin is in direct contact (the polished surface having an epitaxial growth grade, or the roughened surface having a roughness Ra of 25 nm or more).

Hereinafter, experimental results conducted to evaluate the relationship between the weight average molecular weight of the non-bonding amorphous fluororesin and the surface property of the rear surface of the sapphire substrate 11 will be described. According to the experimental results, it was found that as the surface roughness of the rear surface of the sapphire substrate 11 is smaller, in other words, when the rear surface of the sapphire substrate 11 has the polished surface rather than the roughened surface, the weight average molecular weight of the non-bonding amorphous fluororesin is required to have a great value. The specific numerical value of the great value was clear.

A sample of the present light emitting device 1 used for each of the experiments was prepared as follows: 100 μL of a plurality of coating liquids each of which the weight average molecular weight of a non-bonding amorphous fluororesin dissolved in an aprotic fluorine-containing solvent was different was prepared, the coating liquid was injected onto a bare chip of the present light emitting element 10 flip-chip mounted on a submount, and then the solvent was evaporated under heat, to thereby form a first resin portion. The present light emitting element 10 had a chip size of 1 mm×1 mm and a chip thickness of 430 μm. In the present light emitting element 10, sapphire substrates were used in which each of the rear surfaces thereof had a polished surface having an epitaxial growth grade (for Evaluation Experiments 1 and 3), and a sapphire substrate was used in which the rear surface thereof had a roughened surface having an arithmetic average roughness Ra of 25 nm or more (for evaluation experiment 2). As the submount, a base material having 5 mm square made of AlN was used. The number of gold bumps used in the flip-chip mounting is 13 on the p-electrode side and 4 on the n-electrode side.

CYTOP (type S) manufactured by Asahi Glass Co., Ltd. and having a terminal functional group of CF₃ was used as the non-bonding amorphous fluororesin. The weight average molecular weight was adjusted by mixing, at a predetermined weight ratio, a solution (model number: CTL-809S) having a 9% weight concentration of CYTOP (hereinafter, for convenience, “type LS”) that was commercially available from Asahi Glass Co., Ltd. and had a weight average molecular weight (estimated value) of 150,000 with a solution (model number: CTX-809S) having a 9% weight concentration of CYTOP (hereinafter, for convenience, “type XS”) that was commercially available from Asahi Glass Co., Ltd. and had a weight average molecular weight (estimated value) of 250,000. As the aprotic fluorine-containing solvent for each solution, CT-solve 180 manufactured by Asahi Glass Co., Ltd. and having a boiling point of 180° C. was used.

Eight types of coating liquids #1 to #8 shown in Table 1 below were prepared for various evaluation experiments.

TABLE 1

| Coating | Weight average | | |
|---|---|---|---|
| liquid # | molecular weight | Type LS solution | Type XS solution |
| 1 | 150000 | 100 μL | 0 μL |
| 2 | 160000 | 90 μL | 10 μL |
| 3 | 170000 | 80 μL | 20 μL |
| 4 | 190000 | 60 μL | 40 μL |
| 5 | 200000 | 50 μL | 50 μL |
| 6 | 210000 | 40 μL | 60 μL |
| 7 | 230000 | 20 μL | 80 μL |
| 8 | 250000 | 0 μL | 100 μL |

### Evaluation Experiment 1

In Evaluation Experiment 1, prepared were six samples (samples #11A, and #14A to #18A) that were subjected to a series of treatments (hereinafter referred to as “coating treatment”) in which 20 μL of each of six types of coating liquids #1, and #4 to #8 was injected and the solvent was evaporated only once, and six samples (samples #11B, and #14B to #18B) repeatedly subjected to the coating treatment three times. The amount of the resin in the first resin portion of each of the samples repeatedly subjected to the coating treatment three times is three times that of each of the samples subjected to the coating treatment once. The degree of aggregation on the rear surface of the sapphire substrate of the first resin portion was photographed for the total of twelve samples prepared in the above manner. The photograph was visually confirmed, to determine the quality depending on whether or not the first resin portion completely covered the entire rear surface of the sapphire substrate.

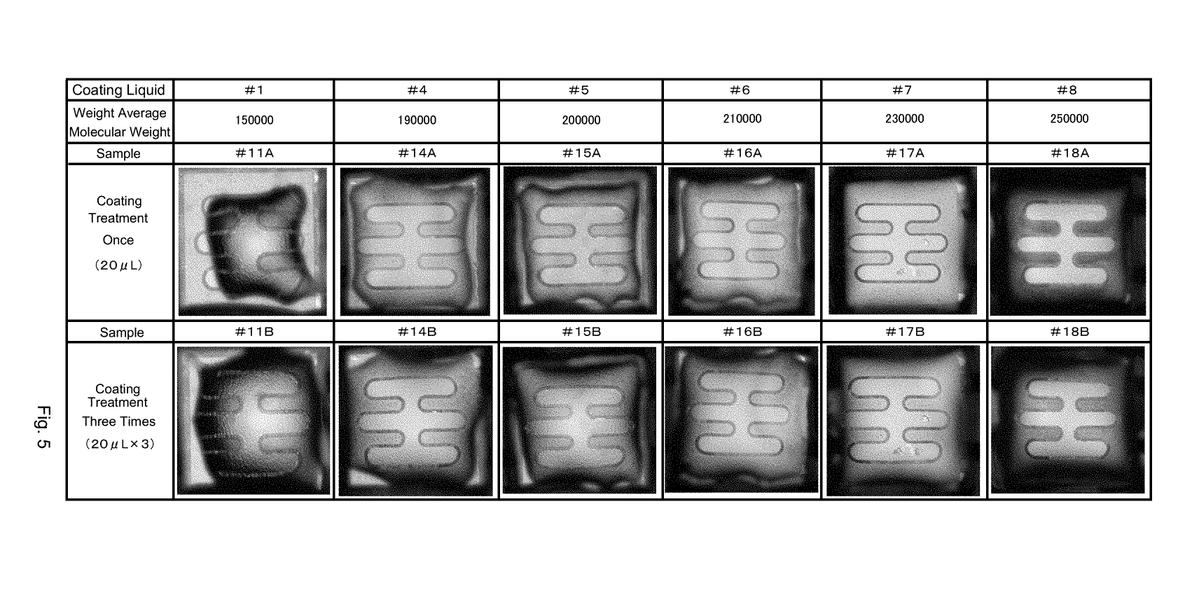

FIG. 5 shows photographs each showing the degree of aggregation on the rear surface of the sapphire substrate of the first resin portion. Each of the photographs is taken from the rear surface side of the sapphire substrate, and is substantially in focus on the p-electrode surface on the surface side of the sapphire substrate. The p-electrode pattern of each of the photographs is seen through the sapphire substrate.

As is apparent from FIG. 5, it is found that, as the weight average molecular weight of the first resin portion is smaller within the range of 150,000 and 250,000 in any of the samples subjected to the coating treatment once and three times, the degree of aggregation of the first resin portion on the rear surface of the sapphire substrate is increased, so that wettability is deteriorated. Furthermore, it is recognized that, when the weight average molecular weight of the first resin portion is 210,000 or less in any of the samples subjected to the coating treatment once and three times, the degree of aggregation is large and the first resin portion does not completely cover the entire rear surface of the sapphire substrate, but when the weight average molecular weight of the first resin portion is 230,000 or more, the first resin portion completely covers the entire rear surface of the sapphire substrate. Therefore, it is found that when the rear surface of the sapphire substrate is the polished surface having an epitaxial growth grade, the weight average molecular weight of the first resin portion is preferably 230,000 or more.

### Evaluation Experiment 2

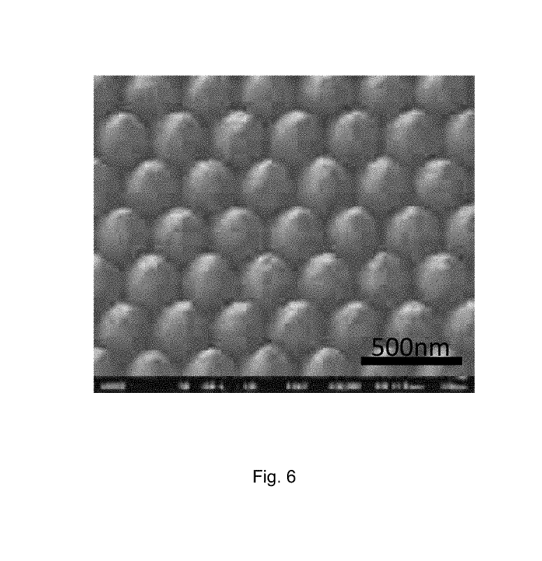

In Evaluation Experiment 2, eight samples (samples #21 to #28) subjected to the coating treatment only once were prepared by using the above-described eight types of coating liquids #1 to #8. In each of the samples #21 to #28, the rear surface of the sapphire substrate having a moth-eye structure shown in FIG. 6 was used in the present light emitting element 10. The substantially conical minute protrusions in the moth-eye structure are regularly arranged in a honeycomb manner in top view. The arrangement pitch is about 300 nm, and the height of each of the minute protrusions is about 100 nm. Accordingly, the moth-eye structure has an arithmetic average roughness Ra of approximately 25 nm.

As with Evaluation Experiment 1, the degree of aggregation on the rear surface of the sapphire substrate of the first resin portion was photographed for the total of eight samples prepared in the above manner. The photograph was visually confirmed, to determine the quality depending on whether or not the first resin portion completely covered the entire rear surface of the sapphire substrate.

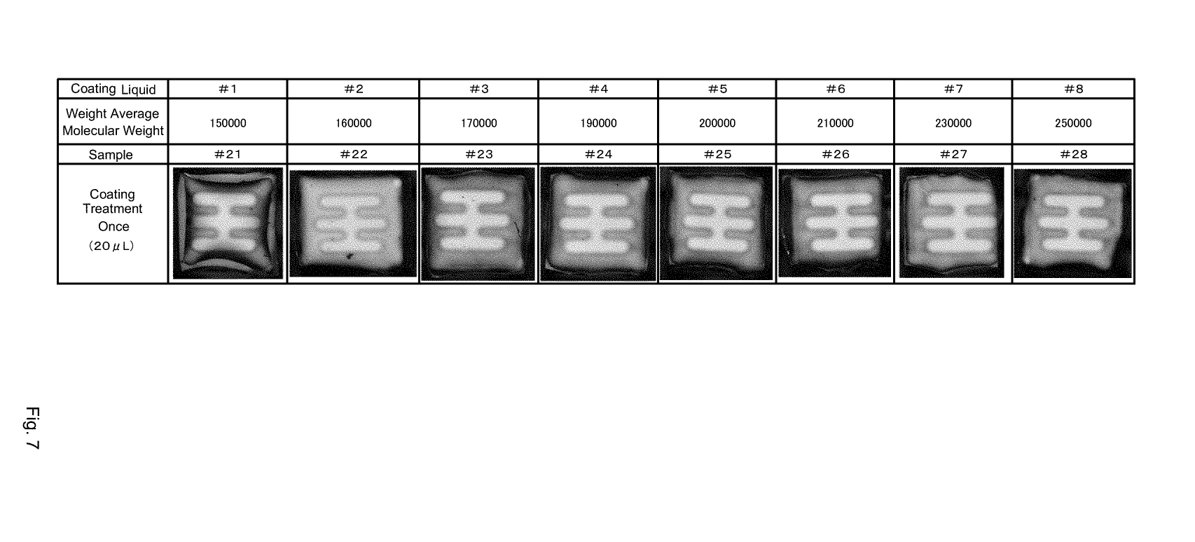

FIG. 7 shows photographs each showing the degree of aggregation on the rear surface of the sapphire substrate of the first resin portion. Each of the photographs is taken from the rear surface side of the sapphire substrate, and is substantially in focus on the p-electrode surface on the surface side of the sapphire substrate. The p-electrode pattern of each of the photographs is seen through the sapphire substrate.

As is apparent from FIG. 7, as with Evaluation Experiment 1 (FIG. 5), that is, regardless of the surface property of the rear surface of the sapphire substrate, it is found that, as the weight average molecular weight of the first resin portion is smaller within the range of 150,000 and 250,000, the degree of aggregation of the first resin portion on the rear surface of the sapphire substrate is increased, so that wettability is deteriorated. Furthermore, it is recognized that, when the weight average molecular weight of the first resin portion is 150,000, the degree of aggregation is large and the first resin portion does not completely cover the entire rear surface of the sapphire substrate, but when the weight average molecular weight of the first resin portion is 160,000 or more, the first resin portion completely covers the entire rear surface of the sapphire substrate.

Comparing the results of Evaluation Experiment 1 (FIG. 5) with the results of Evaluation Experiment 2 (FIG. 7), when the rear surface of the sapphire substrate is the polished surface having an epitaxial growth grade (arithmetic average roughness Ra≤0.3 nm), the lower limit value of the weight average molecular weight of the first resin portion in the suitable range is 230,000. Meanwhile, when the rear surface of the sapphire substrate is the roughened surface (concavoconvex processed surface having a moth-eye structure) having an arithmetic average roughness Ra of 25 nm, the lower limit value of the weight average molecular weight of the first resin portion in the suitable range is as small as 160,000. That is, it is expected that, when the rear surface of the sapphire substrate is a roughened surface having an arithmetic average roughness Ra of greater than 25 nm, the lower limit value of the weight average molecular weight of the first resin portion in the suitable range is even smaller than 160,000. Accordingly, it is found that, when the rear surface of the sapphire substrate is the roughened surface having an arithmetic average roughness Ra of 25 nm or more, the weight average molecular weight of the first resin portion is preferably 160,000 or more.

It is expected that, even when the rear surface of the sapphire substrate is the polished surface having an epitaxial growth grade and if the arithmetic average roughness Ra is greater than 0.3 nm (for example, 0.3 nm<Ra≤1 nm), the lower limit value of the weight average molecular weight of the first resin portion in the suitable range is smaller than 230,000. Accordingly, by setting the weight average molecular weight of the first resin portion to 230,000 or more, the rear surface of the sapphire substrate can have a polished surface having an arithmetic average roughness Ra of greater than 0.3 nm and having an epitaxial growth grade.

### Evaluation Experiment 3

As an additional experiment of Evaluation Experiment 1, by using a coating liquid #6 (weight average molecular weight: 210,000), three samples (samples #36A, #36B, and #36C) were subjected to a coating treatment using 20 μL of the coating liquid once (total coating amount: 20 μL), a coating treatment using 20 μL of the coating liquid three times (total coating amount: 60 μL), and a coating treatment using 100 μL of the coating liquid once (total coating amount: 100 μL). The degree of aggregation on the rear surface of the sapphire substrate of the first resin portion was photographed for the total of twelve samples prepared in the above manner. The photograph was visually confirmed, to determine the quality depending on whether or not the first resin portion completely covered the entire rear surface of the sapphire substrate.

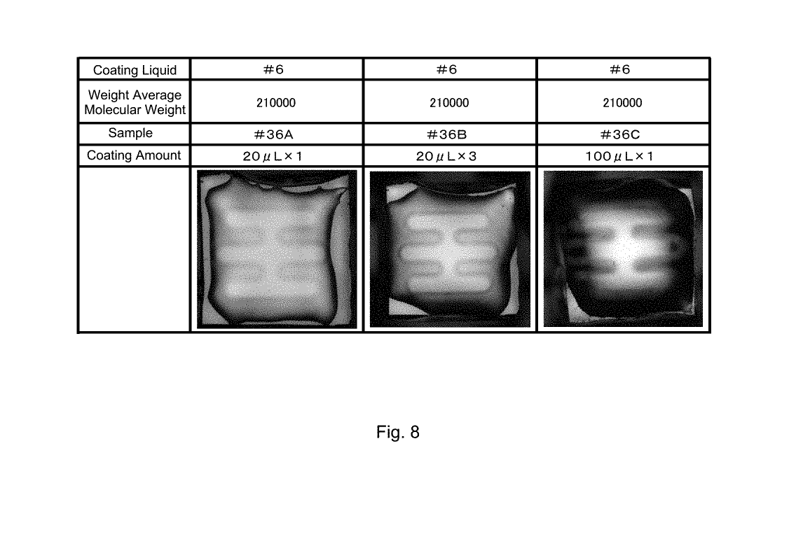

FIG. 8 shows photographs each showing the degree of aggregation on the rear surface of the sapphire substrate of the first resin portion. Each of the photographs is taken from the rear surface side of the sapphire substrate, and is substantially in focus on the p-electrode surface on the surface side of the sapphire substrate. The p-electrode pattern of each of the photographs is seen through the sapphire substrate.

As is apparent from FIG. 8, it is found that, in the case of the total coating amount being within the range of 20 μL to 100 μL, regardless of the total coating amount, when the weight average molecular weight of the first resin portion is 210,000 or less, the degree of aggregation is increased and the first resin portion does not completely cover the entire rear surface of the sapphire substrate, as with the experiment results of Evaluation Experiment 1. That is, it is found that, even when the coating amount of the first resin portion is increased with respect to the same chip size, the results are the same as those when the coating amount is small.

### Evaluation Experiment 4

As an additional experiment of Evaluation Experiment 1, the present light emitting element 10 (chip size: 1.3 mm×1.3 mm, chip thickness: 430 μm, the rear surface of the sapphire substrate: the polished surface having an epitaxial growth grade) having a chip size greater than that of the present light emitting element 10 used in Evaluation Experiment 1 was used, and 20 μL of a coating liquid #8 (weight average molecular weight: 250,000) was used, to prepare one sample (sample #48) subjected to the coating treatment only once.

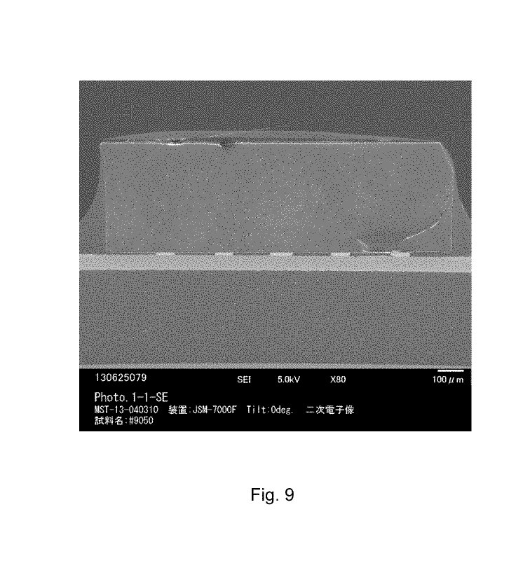

FIG. 9 shows an SEM photograph of a cross section perpendicular to the substrate of the sample #48. It is found that the area of the rear surface of the sapphire substrate is increased by about 70% from 1 mm² to 1.69 mm², but the entire rear surface is completely covered with 20 μL of the same coating liquid in the coating treatment once (total coating amount: 20 μL). However, the film thickness of the first resin portion on the rear surface of the sapphire substrate is thicker at the central portion of the rear surface than at the peripheral portion of the rear surface due to its surface tension. The side surface of the sapphire substrate is completely covered with the first resin portion, although this is understood with difficulty in FIG. 9. However, in the evaporation step of the coating treatment, the coating liquid flows down by gravity, so that the first resin portion covering the side surface has a shape of splaying out. Furthermore, from FIG. 9, it is found that, when the bare chip of the present light emitting element 10 is flip-chip mounted on the submount 30, the gap between the present light emitting element 10 and the submount 30 is also filled with the first resin portion.

### Another Embodiment

Modified examples of the above embodiment will be described below.

<1> In the above embodiment, the case where the p-electrode 14 and the first metal electrode wiring 32 are connected to each other via the gold bump, and the n-electrode 13 and the second metal electrode wiring 33 are connected to each other via the gold bump has been described as one aspect of flip-chip mounting the present light emitting element 10 on the submount 30. However, for example, when the upper surfaces of the p-electrode 14 and n-electrode 13 are formed with uniform height such that the upper surfaces thereof are flush with each other, the p-electrode 14 and the first metal electrode wiring 32 may be physically and electrically connected to each other via a solder material (bonding material) and the n-electrode 13 and the second metal electrode wiring 33 may be physically and electrically connected to each other via a solder material (bonding material), by a well-known soldering method such as a reflow method. As a method for making the height uniform such that the upper surfaces of the p-electrode 14 and n-electrode 13 are flush with each other, for example, it is considered a method for forming a p-side plated electrode that is electrically connected to the p-electrode 14 and that covers the upper and side surfaces of the mesa portion via an insulating protective layer, and forming an n-side plated electrode that is electrically connected to the n-electrode 13 while being separated from the p-side plated electrode with the same height as that of the p-side plated electrode by an electrolytic plating method or the like. For the details of the plated electrode, reference is made to the description of International Application (PCT/JP2015/060588) or the like.

<2> In the above embodiment, the present light emitting device 1 in which one light emitting element 10 is placed on the submount 30 has been described. However, the present light emitting device 1 may be configured such that a plurality of light emitting elements 10 is placed on a base such as a submount or a printed board. In this case, the plurality of light emitting elements 10 may be sealed collectively with the sealing resin 40, or may be individually sealed one by one. In this case, for example, a resin dam surrounding one or a plurality of light emitting elements 1 as a unit to be sealed is formed on the surface of the base. In a region surrounded by the resin dam, for example, the sealing resin 40 is formed as described in the embodiment. The base on which the present light emitting element 10 is placed is not limited to the submount and the printed board.

The present light emitting device 1 in which one light emitting element 10 is placed on the submount 30 may be manufactured as follows. Even when one light emitting element 10 is mounted on the submount 30, the first and second metal electrode wirings 32 and 33 of the plurality of submounts 30 are formed on the surface side of one base material 31, and the lead terminals 34 and 35 of the plurality of submounts 30 are formed on the rear surface side of one base material 31. Each of the plurality of light emitting elements 10 is flip-chip mounted on the plurality of submounts 30 in the submount plate on which the plurality of the submounts 30 are disposed in a matrix form. After the sealing resin 40, or the sealing resin 40 and the lens 41 are formed on the plurality of light emitting elements 10, the submount plate is divided into each of the submounts 30.

### INDUSTRIAL APPLICABILITY

An ultraviolet light emitting device and a method for manufacturing the same according to the present invention can be utilized for an ultraviolet light emitting device obtained by sealing a nitride semiconductor ultraviolet light emitting element such as a light emitting diode having a light emission center wavelength of about 350 nm or less with an amorphous fluororesin, and a method for manufacturing the same.

### DESCRIPTION OF SYMBOLS

1: nitride semiconductor ultraviolet light emitting device
10: nitride semiconductor ultraviolet light emitting element
11: sapphire substrate
12: semiconductor laminated part
13: n-electrode
14: p-electrode
20: AlN layer
21: AlGaN layer
22: n-type clad layer (n-type AlGaN)
23: active layer
24: electron blocking layer (p-type AlGaN)
25: p-type clad layer (p-type AlGaN)
26: p contact layer (p-type GaN)
30: submount
31: base material
32: first metal electrode wiring
320: first electrode pad
321: first wiring part
33: second metal electrode wiring
330: second electrode pad
331: second wiring part
34, 35: lead terminal
40: sealing resin
41: lens

1. An ultraviolet light emitting device comprising:
a base;
a nitride semiconductor ultraviolet light emitting element flip-chip mounted on the base; and
an amorphous fluororesin sealing the nitride semiconductor ultraviolet light emitting element,
wherein
the nitride semiconductor ultraviolet light emitting element includes a sapphire substrate, a plurality of AlGaN-based semiconductor layers laminated on a surface of the sapphire substrate, an n-electrode including one or a plurality of metal layers, and a p-electrode including one or a plurality of metal layers,
a rear surface of the sapphire substrate is a polished surface having an epitaxial growth grade that is the same as an epitaxial growth grade on a surface side of the sapphire substrate, or a roughened surface having a surface roughness greater than a surface roughness of the polished surface and having an arithmetic average roughness Ra of 25 nm or more,
a structural unit of a polymer or copolymer constituting the amorphous fluororesin has a fluorine-containing aliphatic cyclic structure,
in the amorphous fluororesin, a terminal functional group of a polymer or copolymer constituting a first resin portion that is in direct contact with the nitride semiconductor ultraviolet light emitting element is a perfluoroalkyl group, and
when the rear surface of the sapphire substrate is the polished surface, the polymer or copolymer constituting the first resin portion has a weight average molecular weight of 230000 or more, and when the rear surface of the sapphire substrate is the roughened surface, the weight average molecular weight is 160,000 or more.

2. The ultraviolet light emitting device according to claim 1, wherein
the rear surface of the sapphire substrate is a roughened surface having a surface roughness greater than a surface roughness of the polished surface and having an arithmetic average roughness Ra of 25 nm or more, and
the roughened surface is a concavoconvex processed surface formed by two-dimensionally and uniformly dispersing minute protrusions or depressions on an entire rear surface, or a non-polished surface.

3. The ultraviolet light emitting device according to claim 1, wherein the terminal functional group is CF₃.

4. The ultraviolet light emitting device according to claim 1, wherein the nitride semiconductor ultraviolet light emitting element has a light emission center wavelength of 290 nm or less.

5. A method for manufacturing an ultraviolet light emitting device, the ultraviolet light emitting device comprising:
a base;
a nitride semiconductor ultraviolet light emitting element flip-chip mounted on the base; and
an amorphous fluororesin sealing the nitride semiconductor ultraviolet light emitting element,
wherein
the nitride semiconductor ultraviolet light emitting element includes a sapphire substrate, a plurality of AlGaN-based semiconductor layers laminated on a surface of the sapphire substrate, an n-electrode including one or a plurality of metal layers, and a p-electrode including one or a plurality of metal layers,
a rear surface of the sapphire substrate is a polished surface having an epitaxial growth grade that is the same as an epitaxial growth grade on a surface side of the sapphire substrate, or a roughened surface having a surface roughness greater than a surface roughness of the polished surface and having an arithmetic average roughness Ra of 25 nm or more,
a step of forming a first resin portion that is in direct contact with the nitride semiconductor ultraviolet light emitting element in the amorphous fluororesin includes the steps of:
dissolving in a fluorine-containing solvent a first type amorphous fluororesin in which a structural unit of a polymer or copolymer constituting the amorphous fluororesin has a fluorine-containing aliphatic cyclic structure and a terminal functional group of the polymer or copolymer is a perfluoroalkyl group, to prepare a coating liquid;
applying the coating liquid so as to cover an exposed surface of each of the nitride semiconductor ultraviolet light emitting element and the base and to fill a gap part between the nitride semiconductor ultraviolet light emitting element and the base; and
heating the coating liquid to a boiling point or higher of the fluorine-containing solvent and evaporating the fluorine-containing solvent, to form a first resin layer that covers the exposed surface of each of the nitride semiconductor ultraviolet light emitting element and the base and fills the gap part between the nitride semiconductor ultraviolet light emitting element and the base,
when the rear surface of the sapphire substrate is the polished surface, the polymer or copolymer constituting the first type amorphous fluororesin has a weight average molecular weight of 230000 or more, and
when the rear surface of the sapphire substrate is the roughened surface, the weight average molecular weight is 160,000 or more.

6. The method for manufacturing the ultraviolet light emitting device according to claim 5, wherein
the rear surface of the sapphire substrate is a roughened surface having a surface roughness greater than a surface roughness of the polished surface and an arithmetic average roughness Ra of 25 nm or more, and
the roughened surface is a concavoconvex processed surface formed by two-dimensionally and uniformly dispersing minute protrusions or depressions on the entire rear surface, or a non-polished surface.

7. The method for manufacturing the ultraviolet light emitting device according to claim 5, wherein the terminal functional group is CF₃.

8. The method for manufacturing the ultraviolet light emitting device according to claim 5, wherein the nitride semiconductor ultraviolet light emitting element has a light emission center wavelength of 290 nm or less.

9. The method for manufacturing the ultraviolet light emitting device according to claim 5, wherein the fluorine-containing solvent is an aprotic fluorine-containing solvent.
